(19) United States
(12) Patent Application Publication
(10) Pub. No.: US 2023/0223422 A1
(43) Pub. Date: Jul. 13, 2023

(54) DISPLAY DEVICE AND METHOD OF FABRICATING THE SAME

(71) Applicant: Samsung Display Co., LTD., Yongin-si (KR)

(72) Inventors: Sang Jo KIM, Daejeon (KR); Hoo Keun PARK, Cheongju-si (KR); Young Jin SONG, Asan-si (KR)

(73) Assignee: Samsung Display Co., LTD., Yongin-si (KR)

(21) Appl. No.: 17/969,104

(22) Filed: Oct. 19, 2022

(30) Foreign Application Priority Data
Jan. 12, 2022 (KR) 10-2022-0004543

(51) Int. Cl. H01L 27/15; H01L 33/24; H01L 33/18; H01L 33/32; H01L 33/44; H01L 33/00

(52) U.S. Cl. CPC H01L 27/156; H01L 33/007; H01L 33/18; H01L 33/24; H01L 33/44; H01L 33/325

(57) ABSTRACT

A display device includes first banks spaced apart from one another and disposed on a substrate; a first electrode and a second electrode, each disposed on one of the first banks to cover each respective first bank and spaced apart from each other; and a light-emitting element disposed between the first electrode and the second electrode. The light-emitting element includes an active layer, the active layer is in a non-polarized state, and the active layer includes cubic gallium nitride (c-GaN).

### CROSS REFERENCE TO RELATED APPLICATION(S)

This application claims priority to and benefits of Korean Patent Application No. 10-2022-0004543 under 35 U.S.C. §119, filed on Jan. 12, 2022, in the Korean Intellectual Property Office (KIPO), entire contents of which are incorporated herein by reference.

### BACKGROUND

### 1. Technical Field

The disclosure relates to a display device and a method of fabricating the same.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions. Display devices may be flat panel display devices such as a liquid-crystal display device, a field emission display device, or an organic light-emitting display device. Among such flat panel display devices, a light-emitting display device includes a light-emitting element that can emit light on its own, so that each of the pixels of the display panel can emit light by themselves. Accordingly, a light-emitting display device can display images without a backlight unit that supplies light to the display panel.

Such a display panel has a multilayer structure including a bank layer, multiple electrode layers, and multiple insulating layers.

In particular, when a first contact electrode and a second contact electrode are formed on different layers, an element insulating layer for covering the first contact electrode and an element insulating layer for covering the second contact electrode should be formed separately. The cost for equipment for forming the element insulating layers may be additionally incurred.

In view of the above, it may be contemplated that the first contact electrode and the second contact electrode are formed on the same layer. Unfortunately, there is a limit to the resolution or overlay alignment of an exposure machine for forming the first contact electrode and the second contact electrode.

### SUMMARY

Aspects of the disclosure provide a display device including light-emitting elements with improved emission efficiency.

Aspects of the disclosure also provide a method of fabricating a display device including light-emitting elements with improved emission efficiency.

It should be noted that objects of the disclosure are not limited to the above-mentioned object; and other objects of the disclosure will be apparent to those skilled in the art from the following descriptions.

According to an embodiment, a display device may include first banks spaced apart from one another and disposed on a substrate; a first electrode and a second electrode, each disposed on one of the first banks to cover each respective first bank and spaced apart from each other; and a light-emitting element disposed between the first electrode and the second electrode. The light-emitting element may include an active layer, the active layer may be in a non-polarized state, and the active layer may include cubic gallium nitride (c-GaN).

In an embodiment, the active layer may include only cubic gallium nitride (c-GaN).

In an embodiment, the light-emitting element may further include a first semiconductor layer between the active layer and the second electrode and a second semiconductor layer between the active layer and the first electrode.

In an embodiment, the first semiconductor layer may include GaN doped with n-type Si.

In an embodiment, the first semiconductor layer may include n-type Si doped hexagonal gallium nitride (h-GaN) and cubic gallium nitride (c-GaN).

In an embodiment, the second semiconductor layer may include GaN doped with p-type Si.

In an embodiment, the second semiconductor layer may include p-type Si doped hexagonal gallium nitride (h-GaN) and cubic gallium nitride (c-GaN).

In an embodiment, the active layer completely covers the hexagonal gallium nitride (h-GaN) of the first semiconductor layer.

In an embodiment, the display device may further include a first contact electrode electrically connected to the first electrode and contacting the second semiconductor layer of the light-emitting element.

In an embodiment, the display device may further include a second contact electrode electrically connected to the second electrode and contacting the first semiconductor layer of the light-emitting element.

In an embodiment, the display device may further include a first element insulating layer disposed between the first electrode, the second electrode, and the light-emitting element; and a second element insulating layer disposed on an upper surface of the light-emitting element. The first contact electrode may directly contact a portion of an upper surface of the second element insulating layer, the second contact electrode may directly contact another portion of the upper surface of the second element insulating layer, and each first contact electrode and the second contact electrode may expose a central portion of the upper surface of the second element insulating layer.

In an embodiment, the display device may further include a third element insulating layer integrally formed to cover the first contact electrode and the second contact electrode and may contact the first contact electrode and the second contact electrode.

According to another embodiment, a method of fabricating a display device, the method may include preparing a substrate on which first banks spaced apart from one another are disposed; forming a first electrode and a second electrode on one of the first banks to cover respective first bank, the first electrode and the second electrode being spaced apart from each other; forming a first element insulating layer on the first electrode and the second electrode; and disposing a light-emitting element on the first element insulating layer. The disposing the light-emitting element may include forming the light-emitting element, and disposing the light-emitting element between the first electrode and the second electrode. The forming the light-emitting element may include disposing second banks on an unetched portion of a silicon substrate comprising the unetched portion and an etched portion; growing first hexagonal gallium nitride (h-GaN) on the etched portion; growing first cubic gallium nitride (c-GaN) on the first hexagonal gallium nitride (h-GaN); and growing second hexagonal gallium nitride (h-GaN) and/or second cubic gallium nitride (c-GaN) on the grown cubic gallium nitride (c-GaN).

In an embodiment, the light-emitting element may include an active layer, a first semiconductor layer between the active layer and the second electrode, and a second semiconductor layer between the active layer and the first electrode.

In an embodiment, the active layer may be formed only of cubic gallium nitride (c-GaN).

In an embodiment, the second banks may include silicon oxide, and a distance between the second banks may be in a range of about 5,800 nm to about 6,000 nm.

In an embodiment, the etched portion may include a first etched surface, and a second etched surface between the first etched surface and an upper surface of the unetched portion. The second etched surface may be inclined with respect to the first etched surface.

In an embodiment, a depth of the first etched surface may be in a range of about 50 nm to about 150 nm.

In an embodiment, a height of the active layer from the upper surface of the unetched portion of the silicon substrate may be in a range of about 50 nm to about100 nm.

In an embodiment, the growing the first cubic gallium nitride (c-GaN) on the first hexagonal gallium nitride (h-GaN) may include growing the first cubic gallium nitride (c-GaN) to completely cover the first hexagonal gallium nitride (h-GaN).

According to embodiments of the disclosure, it is possible to improve the efficiency of light-emitting elements.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a plan view showing a display device according to an embodiment of the disclosure.

FIG. 2 is an enlarged schematic cross-sectional view taken along line I - I′ of FIG. 1.

FIG. 3 is a plan view showing a single pixel of a display device according to an embodiment of the disclosure.

FIG. 4 is a schematic cross-sectional view taken along line II - II′ of FIG. 3.

FIG. 5 is a perspective view showing a light-emitting element according to an embodiment of the disclosure.

FIGS. 6A and 6B are perspective views showing hexagonal gallium nitride (h-GaN/Wurtzite GaN) and cubic gallium nitride (c-GaN), respectively.

FIGS. 7A and 7B are views showing energy bands of hexagonal gallium nitride (h-GaN/Wurtzite GaN) and cubic gallium nitride (c-GaN), respectively.

FIG. 8 is a flowchart for illustrating a method for fabricating a display device according to an embodiment of the disclosure.

FIGS. 9 to 11 are schematic cross-sectional views showing processing steps of a method of fabricating a display device according to an embodiment of the disclosure.

FIG. 12 is a perspective view showing a light-emitting element according to another embodiment of the disclosure.

FIG. 13 is a perspective view showing a light-emitting element according to yet another embodiment of the disclosure.

### DETAILED DESCRIPTION OF THE EMBODIMENTS

Specific structural and functional descriptions of embodiments disclosed herein are only for illustrative purposes of the embodiments. The disclosure may be embodied in many different forms without departing from the spirit and significant characteristics of the disclosure. Therefore, the embodiments are disclosed only for illustrative purposes and should not be construed as limiting the disclosure. The disclosure is only defined by the scope of the claims.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Other expressions that explain the relationship between elements, such as “between,” “directly between,” “adjacent to,” or “directly adj acent to,” should be construed in the same way. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Throughout the specification, the same reference numerals will refer to the same or like parts.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, embodiments of the disclosure will be described in detail with reference to the accompanying drawings.

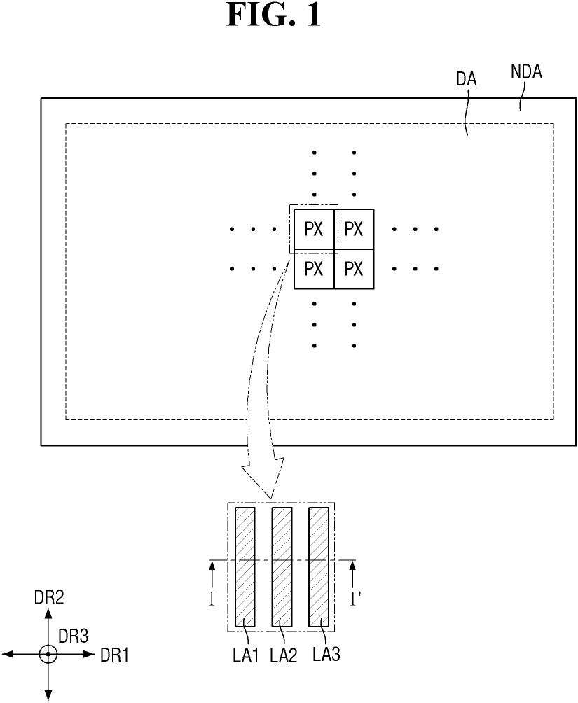

FIG. 1 is a plan view showing a display device according to an embodiment of the disclosure.

Referring to FIG. 1, a display device according to an embodiment of the disclosure may have a rectangular shape in a plan view. It is, however, to be understood that the disclosure is not limited thereto. The shape of the display device in a plan view may be a square, a circle, an ellipse, or other polygons. In the following description, the display device has a rectangular shape in a plan view.

The display device may include a display panel that provides a display screen. Examples of the display panel may include an inorganic light-emitting diode display panel, an organic light-emitting display panel, a quantum-dot light-emitting display panel, a plasma display panel, a field emission display panel, etc. In the following description, an inorganic light-emitting diode display panel is employed as an embodiment of the display panel 10, but the disclosure is not limited thereto. Any other display panel may be employed as long as the technical idea of the disclosure can be equally applied.

The display device may include a display area DA and a non-display area NDA. The display area DA may include multiple pixels PX to display images. The multiple pixels PX may be arranged in a matrix pattern. The non-display area NDA may be disposed adj acent to the display area DA to surround the display area DA, and may display no image. The non-display area NDA may completely surround the display area DA in a plan view. The display area DA may be referred to as an active area, while the non-display area NDA may be referred to as an inactive area. The display area DA may generally occupy the center of the display device.

The non-display area NDA may be located on one side and an opposite side of the display device in a first direction DR1, and one side and an opposite side of the display device in a second direction DR2. It is, however, to be understood that the disclosure is not limited thereto. The non-display area NDA may be located only on one side and the opposite side in the first direction DR1, or only on one side and the opposite side in the second direction DR2. Lines or circuit drivers included in the display device may be disposed or external devices may be mounted in the non-display area NDA.

Referring to the enlarged view of FIG. 1, each of the pixels PX of the display device may include light-emitting areas LA1, LA2, and LA3 defined by a pixel-defining layer, and may emit light having a predetermined (or selectable) peak wavelength through the light-emitting areas LA1, LA2, and LA3. For example, the display area DA of each of the display devices may include first to third light-emitting areas LA1, LA2, and LA3. In each of the first to third light-emitting areas LA1, LA2, and LA3, light generated by light-emitting elements of the display devices exits out of the display devices.

The first to third light-emitting areas LA1, LA2, and LA3 may emit light having predetermined (or selectable) peak wavelengths to the outside of the display devices. The first light-emitting area LA1 may emit light of a first color, the second light-emitting area LA2 may emit light of a second color, and the third light-emitting area LA3 may emit light of a third color. For example, the light of the first color may be red light having a peak wavelength in the range of about 610 to about 650 nm, the light of the second color may be green light having a peak wavelength in the range of about 510 to about 550 nm, and the light of the third color may be blue light having a peak wavelength in the range of about 440 to about 480 nm. It is, however, to be understood that the disclosure is not limited thereto.

The display area DA of the display device may include light-blocking areas located between the adjacent ones of the light-emitting areas LA1, LA2, and LA3. For example, the light-blocking areas between the light-emitting areas may surround the first light-emitting area LA1 to the third light-emitting area LA3.

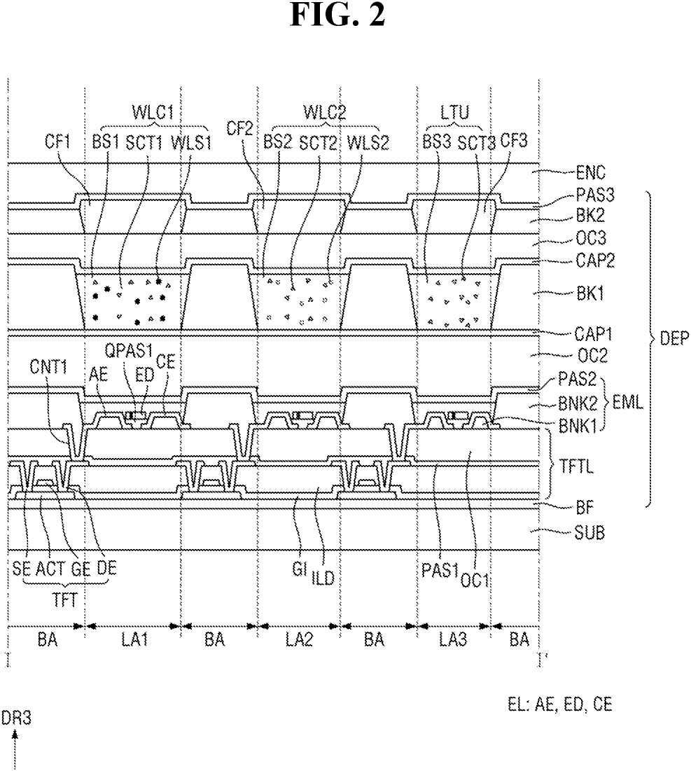

FIG. 2 is an enlarged schematic cross-sectional view taken along line I - I′ of FIG. 1.

Referring to FIG. 2, the display device may include a substrate SUB disposed across the display area DA and the non-display area NDA, a display element layer DEP on the substrate SUB disposed in the display area DA, and an encapsulation member ENC disposed across the display area DA and the non-display area NDA to encapsulate the display element layer DEP.

The substrate SUB may be made of an insulating material such as polymer resin. The insulating material may include, but is not limited to, polyimide (PI).

The display element layer DEP may include a buffer layer BF, a thin-film transistor layer TFTL, an emission layer EML, a second planarization layer OC2, a first capping layer CAP1, a first light-blocking member BK1, a first wavelength-converting part WLC1, a second wavelength-converting part WLC2, a light-transmitting part LTU, a second capping layer CAP2, a third planarization layer OC3, a second light-blocking member BK2, first to third color filters CF1, CF2, and CF3, a third passivation layer PAS3, and an encapsulation member ENC.

The buffer layer BF may be disposed on the substrate 100. The buffer layer BF may be formed of an inorganic film that can prevent the permeation of air or moisture.

The thin-film transistor layer TFTL may include a thin-film transistor TFT, a gate insulator GI, an interlayer dielectric film ILD, a first passivation layer PAS1, and a first planarization layer OC1.

The thin-film transistor TFT may be disposed on the buffer layer BF, and may form a pixel circuit of each of pixels.

The semiconductor layer ACT may be disposed on the buffer layer BF. The semiconductor layer ACT may overlap the gate electrode GE, the source electrode SE, and the drain electrode DE. The semiconductor layer ACT may directly contact the source electrode SE and the drain electrode DE, and may face the gate electrode GE with the gate insulating layer GI therebetween.

The gate electrode GE may be disposed on the gate insulator GI. The gate electrode GE may overlap the semiconductor layer ACT with the gate insulating layer GI interposed therebetween.

The source electrode SE and the drain electrode DE may be disposed on the interlayer dielectric layer ILD such that they are spaced apart from each other. The source electrode SE may contact an end of the semiconductor layer ACT through a contact hole formed in the gate insulating layer GI and the interlayer dielectric layer ILD. The drain electrode DE may contact another end of the semiconductor layer ACT through a contact hole formed in the gate insulating layer GI and the interlayer dielectric layer ILD. The drain electrode DE may be electrically connected to a first electrode AE of a light-emitting element EL through a contact hole formed in the first passivation layer PAS1 and the first planarization layer OC1.

The gate insulator GI may be disposed on the semiconductor layer ACT. For example, the gate insulating layer GI may be disposed on the semiconductor layer ACT and the buffer layer BF, and may insulate the semiconductor layer ACT from the gate electrode GE. The gate insulating layer GI may include a contact hole through which the source electrode SE penetrates and a contact hole through which the drain electrode DE penetrates.

The interlayer dielectric layer ILD may be disposed over the gate electrode GE. For example, the interlayer dielectric layer ILD may include a contact hole through which the source electrode SE penetrates, and a contact hole through which the drain electrode DE penetrates.

The first passivation layer PAS1 may be disposed above the thin-film transistor TFT to protect the thin-film transistor TFT. For example, the first passivation layer PAS1 may include a contact hole through which the first electrode AE penetrates.

The first planarization layer OC1 may be disposed on the first passivation layer PAS1 to provide a flat surface over the thin-film transistor TFT. For example, the first planarization layer OC1 may include a contact hole through which the first electrode AE of the light-emitting element EL penetrates.

The emission layer EML may include a light-emitting element EL, first banks BNK1, second banks BNK2, a first element insulating layer QPAS1, and a second passivation layer PAS2.

The light-emitting element EL may be disposed on the thin-film transistor TFT. The light-emitting element EL may include a first electrode AE, a second electrode CE, and a light-emitting element ED.

The first electrode AE may be disposed on the first planarization layer OC1. For example, the first electrode AE may be disposed over the first banks BNK1 disposed on the first planarization layer OC1 to cover the first bank BNK1. The first electrode AE may be disposed to at least partially overlap one of the first to third light-emitting areas LA1, LA2, and LA3 defined by the second banks BNK2. The first electrode AE may be electrically connected to the drain electrode DE of the thin-film transistor TFT.

The second electrode CE may be disposed on the first planarization layer OC1. For example, the second electrode CE may be disposed over the first banks BNK1 disposed on the first planarization layer OC1 to cover the first banks BNK1. The second electrode CE may be disposed to at least partially overlap one of the first to third light-emitting areas LA1, LA2, and LA3 defined by the second banks BNK2. For example, the second electrode CE may receive a common voltage applied to all pixels.

The first element insulating layer QPAS1 may cover a part of the first electrode AE and a part of the second electrode CE adjacent to each other and may insulate the first and second electrodes AE and CE from each other.

The light-emitting element ED may be disposed between the first electrode AE and the second electrode CE above the first planarization layer OC1. The light-emitting element ED may be disposed on the first element insulating layer QPAS1. A first end of the light-emitting element ED may be electrically connected to the first electrode AE, and a second end of the light-emitting element ED may be electrically connected to the second electrode CE. For example, the light-emitting elements ED may include active layers having the same material so that they may emit light of the same wavelength or light of the same color. The lights emitted from the first to third light-emitting areas LA1, LA2, and LA3, respectively, may have the same color. For example, the light-emitting elements ED may emit light of the third color or blue light having a peak wavelength in the range of about 440 nm to about 480 nm.

The second banks BNK2 may be disposed on the first planarization layer OC1 to define first to third light-emitting areas LA1, LA, and LA3. For example, the second banks BNK2 may surround each of the first to third light-emitting areas LA1, LA2, and LA3. It is, however, to be understood that the disclosure is not limited thereto. The second banks BNK2 may be disposed in each of the light-blocking areas BA.

The second passivation layer PAS2 may be disposed on the light-emitting elements EL and the second banks BNK2. The second passivation layer PAS2 may cover the light-emitting elements EL to protect the light-emitting elements EL.

The display device may further include the second planarization layer OC2, the first capping layer CAP1, the first light-blocking member BK1, the first wavelength converting part WLC1, the second wavelength converting part WLC2, the light-transmitting part LTU, the second capping layer CAP2, the third planarization layer OC3, the second light-blocking member BK2, the first to third color filters CF1, CF2, and CF3, the third passivation layer PAS3, and the encapsulation member ENC.

The second planarization layer OC2 may be disposed on the emission layer EML to provide a flat surface over the emission layer EML. The second planarization layer OC2 may include an organic material.

The first capping layer CAP1 may be disposed on the second planarization layer OC2. The first capping layer CAP1 may seal the lower surfaces of the first and second wavelength converting parts WLC1 and WLC2 and the light-transmitting part LTU. The first capping layer CAP1 may include an inorganic material.

The first light-blocking member BK1 may be disposed on the first capping layer CAP1 in the light-blocking areas BA. The first light-blocking member BK1 may overlap the second banks BNK2 in the thickness direction. The first light-blocking member BK1 may block the transmission of light.

The first light-blocking member BK1 may include an organic light-blocking material and a liquid repellent component.

Since the first light-blocking member BK1 includes a liquid repellent component, the first and second wavelength converting parts WLC1 and WLC2 and the light-transmitting part LTU may be separated so that they can correspond to the respective light-emitting areas LA.

The first wavelength converting part WLC1 may be disposed in the first emission area LA1 on the first capping layer CAP1. The first wavelength converting part WLC1 may be surrounded by the first light blocking member BK1. The first wavelength-converting part WLC1 may include a first base resin BS1, first scatterers SCT1, and first wavelength shifters WLS1.

The first base resin BS1 may include a material having a relatively high light transmittance. The first base resin BS1 may be made of a transparent organic material. For example, the first base resin BS1 may include at least one organic material including an epoxy resin, an acrylic resin, a cardo resin, or an imide resin.

The first scatterers SCT1 may have a refractive index different from that of the first base resin BS1 and may form an optical interface with the first base resin BS1. For example, first scatterers SCT1 may include a light scattering material or light scattering particles that scatter at least a part of transmitted light.

The first wavelength shifters WLS1 may convert or shift the peak wavelength of the incident light to a first peak wavelength. For example, the first wavelength shifters WLS1 may convert blue light provided from the emission layer EML into red light having a single peak wavelength in the range of about 610 nm to about 650 nm, and output the light. The first wavelength shifters WLS1 may be quantum dots, quantum rods, or phosphors. The quantum dots may be particulate matter that emits a color as electrons transition from the conduction band to the valence band.

The light output from the first wavelength shifters WLS1 may have a full width of half maximum (FWHM) of the emission wavelength spectrum of about 45 nm or less, about 40 nm or less, or about 30 nm or less. Accordingly, the color purity and color gamut of the colors displayed by the display device may be further improved.

A part of the blue light emitted from the emission layer EML may pass through the first wavelength-converting part WLC1 without being converted into red light by the first wavelength shifters WLS1. In case that such blue light is incident on the first color filter CF1, it may be blocked by the first color filter CF1. On the other hand, red light converted by the first wavelength-converting part WLC1 may pass through the first color filter CF1 to exit to the outside. Accordingly, the first light-emitting area LA1 may emit red light.

The second wavelength-converting part WLC2 may be disposed in the second light-emitting area LA2 on the first capping layer CAP1. The second wavelength-converting part WLC2 may be surrounded by the first light-blocking member BK1. The second wavelength-converting part WLC2 may include a second base resin BS2, second scatterers SCT2, and second wavelength shifters WLS2.

The second base resin BS2 may include a material having a relatively high light transmittance. The second base resin BS2 may be made of a transparent organic material. The second base resin BS2 may include at least one organic material, as described above for the first base resin BS1.

The second scatterers SCT2 may have a refractive index different from that of the second base resin BS2 and may form an optical interface with the second base resin BS2. For example, the second scatterers SCT2 may include a light scattering material or light scattering particles that scatter at least a part of transmitted light.

The second wavelength shifters WLS2 may convert or shift the peak wavelength of the incident light to a second peak wavelength that is different from the first peak wavelength of the first wavelength shifters WLS1. For example, the second wavelength shifters WLS2 may convert blue light provided from the emission layer EML into green light having a single peak wavelength in the range of about 510 nm to about 550 nm, and output the light. The second wavelength shifters WLS2 may be quantum dots, quantum rods, or phosphor. The second wavelength shifters WLS2 may be particulate matter as described for the first wavelength shifters WLS1.

The light output from the second wavelength shifters WLS2 may have a full width of half maximum (FWHM) of the emission wavelength spectrum of about 45 nm or less, about 40 nm or less, or about 30 nm or less. Accordingly, the color purity and color gamut of the colors displayed by the display device may be further improved.

A part of the blue light emitted from the emission layer EML may pass through the second wavelength-converting part WLC2 without being converted into green light by the second wavelength shifters WLS2. In case that such blue light is incident on the second color filter CF2, it may be blocked by the second color filter CF2. On the other hand, green light converted by the second wavelength-converting part WLC2 may pass through the second color filter CF2 to exit to the outside. Accordingly, the second light-emitting area LA1 may emit green light.

The light-transmitting part LTU may be disposed in the third light-emitting area LA3 on the first capping layer CAP1. The light-transmitting part LTU may be surrounded by the first light-blocking member BK1. The light-transmitting part LTU may transmit the incident light without converting its peak wavelength. The light-transmitting part LTU may include a third base resin BS3 and third scatterers SCT3.

The third base resin BS3 may include a material having a relatively high light transmittance. The third base resin BS3 may be made of a transparent organic material.

The third scatterers SCT3 may have a refractive index different from that of the third base resin BS3 and may form an optical interface with the third base resin BS3. For example, the third scatterers SCT3 may include a light scattering material or light scattering particles that scatter at least a part of transmitted light.

The first and second wavelength converting parts WLC1 and WLC2 and the light-transmitting part LTU may be disposed on the emission layer EML, the second planarization layer OC2, and the first capping layer CAP1. Therefore, the display device may not require a separate substrate for the first and second wavelength converting parts WLC1 and WLC2 and the light-transmitting part LTU.

The second capping layer CAP2 may cover the first and second wavelength converting parts WLC1 and WLC2, the light-transmitting part LTU, and the first light-blocking member BK1.

The third planarization layer OC3 may be disposed on the second capping layer CAP2 to provide flat top surfaces of the first and second wavelength converting parts WLC1 and WLC2 and the light-transmitting part LTU. The third planarization layer OC3 may include an organic material.

The second light-blocking member BK2 may be disposed on the third planarization layer OC3 in the light-blocking areas BA. The second light-blocking member BK2 may overlap the first light-blocking member BK1 or the second banks BNK2 in the thickness direction. The second light-blocking member BK2 may block the transmission of light.

The first color filter CF1 may be disposed in the first light-emitting area LA1 on the third planarization layer OC3. The first color filter CF1 may be surrounded by the second light blocking member BK2. The first color filter CF1 may overlap the first wavelength-converting part WLC1 in the thickness direction. The first color filter CF1 may selectively transmit light of the first color (e.g., red light) and may block and absorb light of the second color (e.g., green light) and light of the third color (e.g., blue light).

The second color filter CF2 may be disposed on the third planarization layer OC3 in the second light-emitting area LA2. The second color filter CF2 may be surrounded by the second light-blocking member BK2. The second color filter CF2 may overlap the second wavelength-converting part WLC2 in the thickness direction. The second color filter CF2 may selectively transmit light of the second color (e.g., green light) and may block and absorb light of the first color (e.g., red light) and light of the third color (e.g., blue light).

The third color filter CF3 may be disposed in the third light-emitting area LA3 on the third planarization layer OC3. The third color filter CF3 may be surrounded by the second light-blocking member BK2. The third color filter CF3 may overlap the light-transmitting part LTU in the thickness direction. The third color filter CF3 may selectively transmit light of the third color (e.g., blue light) and may block and absorb light of the first color (e.g., red light) and light of the second color (e.g., green light).

The first to third color filters CF1, CF2, and CF3 may absorb a part of the light introduced from the outside of the display device to reduce reflection of external light. Accordingly, the first to third color filters CF1, CF2, and CF3 may prevent color distortion due to reflection of external light.

The third passivation layer PAS3 may cover the first to third color filters CF1, CF2, and CF3. The third passivation layer PAS3 may protect the first to third color filters CF1, CF2, and CF3.

The encapsulation member ENC may be disposed on the third passivation layer PAS3. For example, the encapsulation member ENC may include at least one inorganic layer to prevent permeation of oxygen or moisture. The encapsulation member ENC may include at least one organic layer to protect the display device from foreign substances such as dust.

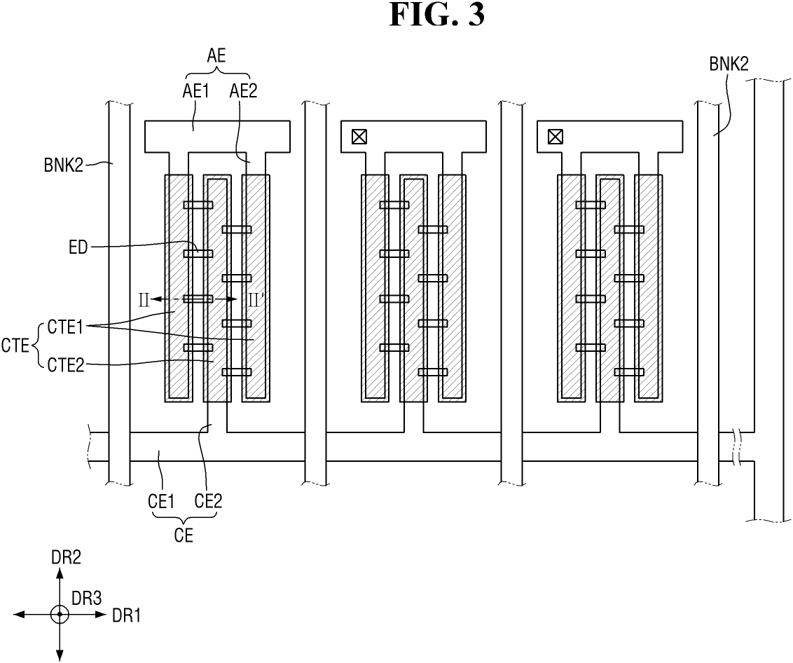

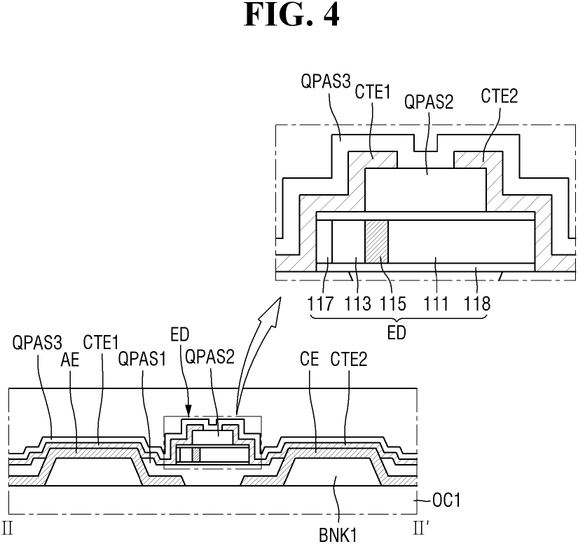

FIG. 3 is a plan view showing a single pixel of a display device according to an embodiment of the disclosure. FIG. 4 is a schematic cross-sectional view taken along line II - II′ of FIG. 3.

Referring to FIGS. 3 and 4 in conjunction with FIG. 2, each of the pixels may include first to third sub-pixels. The first to third sub-pixels may correspond to the first to third light-emitting areas LA1, LA2, and LA3, respectively. The light-emitting elements ED of each of the first to third sub-pixels may emit light through the first to third light-emitting areas LA1, LA2, and LA3.

The first to third sub-pixels may emit light of the same color. For example, each of the first to third sub-pixels may include the light-emitting elements ED of the same type, and may emit light of the third color or blue light. For another example, the first sub-pixel may emit light of the first color or red light, the second sub-pixel may emit light of the second color or green light, and the third sub-pixel may emit light of the third color or blue light.

Each of the first to third sub-pixels may include first and second electrodes AE and CE, light-emitting elements ED, multiple contact electrodes CTE, and multiple first banks BNK1.

The first and second electrodes AE and CE may be electrically connected to the light-emitting elements ED and may receive a predetermined (or selectable) voltage, and the light-emitting elements ED may emit light of a certain wavelength band. At least a part of the first and second electrodes AE and CE may form an electric field in the pixel, and the light-emitting elements ED may be aligned by the electric field.

For example, the first electrode AE may be a pixel electrode disposed separately in each of the first to third sub-pixels, while the second electrode CE may be a common electrode commonly connected to the first to third sub-pixels. One of the first electrode AE and the second electrode CE may be an anode electrode of the light-emitting elements ED, while the other may be a cathode electrode of the light-emitting elements ED.

The first electrode AE may include a first electrode stem AE1 extended in the first direction DR1, and at least one first electrode branch AE2 branching off from the first electrode stem AE1 and extended in the second direction DR2.

The first electrode stem AE1 of each of the first to third sub-pixels may be spaced apart from the first electrode stem AE1 of an adjacent sub-pixel, and the first electrode stems AE1 may be disposed on an imaginary extension line with the first electrode stem AE1 of the sub-pixel adjacent in the first direction DR1. The first electrode stems AE1 of the first to third sub-pixels may receive different signals, respectively, and may be driven individually.

The first electrode branch AE2 may branch off from the first electrode stem AE1 and may be extended in the second direction DR2. One end of the first electrode branch AE2 may be electrically connected to the first electrode stem AE1, while the other end of the first electrode branch AE2 may be spaced apart from the second electrode stem CE1 opposed to the first electrode stem AE1.

The second electrode CE may include a second electrode stem CE1 extended in the first direction DR1, and a second electrode branch CE2 branching off from the second electrode stem CE1 and extended in the second direction DR2. The second electrode stem CE1 of each of the first to third sub-pixels may be electrically connected to the second electrode stem CE1 of an adjacent sub-pixel. The second electrode stem CE1 may be extended in the first direction DR1 to traverse the multiple pixels. The second electrode stem CE1 may be electrically connected to a portion extended in a direction at the outer portion of the display area DA or in the non-display area NDA.

The second electrode branch CE2 may be spaced apart from and face the first electrode branch AE2. One end of the second electrode branch CE2 may be electrically connected to the second electrode stem CE1, while the other end of the second electrode branch CE2 may be spaced apart from the first electrode stem AE1.

The first electrode AE may be electrically connected to the thin-film transistor layer TFTL of the display device through a first contact hole CNT1, and the second electrode CE may be electrically connected to the thin-film transistor layer TFTL of the display device through a second contact hole CNT2 (not shown). For example, the first contact hole CNT1 may be formed in each of the first electrode branches AE2, and the second contact hole CNT2 (not shown) may be formed in the second electrode stem CE1. It is, however, to be understood that the disclosure is not limited thereto.

The second banks BNK2 may be disposed at the boundary between the pixels. The multiple first electrode branches AE2 may be spaced apart from one another with respect to the second banks BNK2. The second banks BNK2 may be extended in the second direction DR2 and may be disposed at the boundaries of the pixels SP arranged in the first direction DR1. The second banks BNK2 may be disposed at the boundaries of the pixels SP arranged in the second direction DR2 as well. The second banks BNK2 may define the boundaries of the pixels.

In case that an ink in which the light-emitting elements ED are dispersed is sprayed during the process of fabricating the display device, the second banks BNK2 may prevent the ink from flowing over the boundaries of the pixels SP. The second banks BNK2 may separate the inks in which different light-emitting elements ED are dispersed so that the inks are not mixed with each other.

The light-emitting elements ED may be disposed between the first electrode AE and the second electrode CE. One end of the light-emitting element ED may be electrically connected to the first electrode AE, and the second end of the light-emitting element ED may be electrically connected to the second electrode CE.

The light-emitting elements ED may be spaced apart from one another and may be substantially aligned in parallel with one another. The spacing between the light-emitting elements ED is not particularly limited herein.

The multiple light-emitting elements ED may include active layers having the same material so that they may emit light of the same wavelength range or light of the same color. The first to third sub-pixels may emit light of the same color. For example, the multiple light-emitting elements ED may emit light of the third color or blue light having a peak wavelength in the range of about 440 nm to about 480 nm.

The contact electrodes CTE may include first and second contact electrodes CTE1 and CTE2. The first contact electrode CTE1 may cover the first electrode branch AE2 and parts of the light-emitting elements ED, and may electrically connect the first electrode branch AE2 with the light-emitting elements ED. The second contact electrode CTE2 may cover the second electrode branch CE2 and other parts of the light emitting diodes ED, and may electrically connect the second electrode branch CE2 and the light emitting diodes ED.

The first contact electrode CTE1 may be disposed on the first electrode branch AE2 and extended in the second direction DR2. The first contact electrode CTE1 may contact first ends of the light-emitting elements ED. The light-emitting elements ED may be electrically connected to the first electrode AE through the first contact electrode CTE1.

The second contact electrode CTE2 may be disposed on the second electrode branch CE2 and extended in the second direction DR2. The second contact electrode CTE2 may be spaced apart from the first contact electrode CTE1 in the first direction DR1. The second contact electrode CTE2 may contact second ends of the light-emitting elements ED. The light-emitting elements ED may be electrically connected to the second electrode CE through the second contact electrode CTE2.

The emission layer EML of the display device may be disposed on the thin-film transistor layer TFTL, and may include first to third element insulating layers QPAS1, QPAS2, and QPAS3.

The multiple first banks BNK1 may be disposed in the first to third light-emitting areas LA1, LA2, and LA3, respectively. Each of the first banks BNK1 may be associated with the first electrode AE or the second electrode CE. Each of the first and second electrodes AE and CE may be disposed on the respective first bank BNK1. For example, the first banks BNK1 may be disposed on the first planarization layer OC1, and the side surfaces of each of the first banks BNK1 may be inclined from the first planarization layer OC1. The inclined surfaces of the first banks BNK1 may reflect light emitted from the light-emitting elements ED.

The first electrode stem AE1 may include the first contact hole CNT1 penetrating through the first planarization layer OC1. The first electrode stem AE1 may be electrically connected to the thin-film transistor TFT through the first contact hole CNT1.

The second electrode stem CE1 may be extended in the first direction DR1 and may be disposed also in a non-light-emitting area where the light-emitting elements ED are not disposed. The second electrode branch CE2 may include the second contact hole CNT2 (not shown) penetrating through the first planarization layer OC1. The second electrode stem CE1 may be electrically connected to a power electrode through the second contact hole CNT2 (not shown). The second electrode CE may receive a predetermined (or selectable) electric signal from the power electrode.

The first and second electrodes AE and CE may include a transparent conductive material. The first and second electrodes AE and CE may include a conductive material with high reflectivity. The first and second electrodes AE and CE may be made up of a stack of one or more transparent conductive materials and one or more metals having high reflectivity or a single layer including them.

The first element insulating layer QPAS1 may be disposed on the first planarization layer OC1, the first electrode AE, and the second electrode CE. The first element insulating layer QPAS1 may partially cover each of the first and second electrodes AE and CE.

The first element insulating layer QPAS1 may protect the first and second electrodes AE and CE and may insulate the first and second electrodes AE and CE from each other. The first element insulating layer QPAS1 may prevent the light-emitting elements ED directly contacting other elements and being damaged by them.

The light-emitting elements ED may be disposed on the first element insulating layer QPAS1 between the first electrode AE and the second electrode CE. One ends of the light-emitting elements ED may be electrically connected to the first electrode AE, and the second ends of the light-emitting elements ED may be electrically connected to the second electrode CE.

The second element insulating layer QPAS2 may be disposed on the light-emitting elements ED disposed between the first electrode AE and the second electrode CE. The second element insulating layer QPAS2 may be disposed at the center of the upper surface of the light-emitting elements ED. The third element insulating layer QPAS3 may partially surround the outer surface of the light-emitting elements ED. The third element insulating layer QPAS3 may protect the light-emitting elements ED. The third element insulating layer QPAS3 may surround the outer surface of the light-emitting elements ED.

The contact electrodes CTE may include first and second contact electrodes CTE1 and CTE2. The first contact electrode CTE1 may cover the first electrode branch AE2 and parts of the light-emitting elements ED, and may electrically connect the first electrode branch AE2 with the light-emitting elements ED. The second contact electrode CTE2 may cover the second electrode branch CE2 and other parts of the light emitting diodes ED, and may electrically connect the second electrode branch CE2 and the light emitting diodes ED.

The first contact electrode CTE1 may be disposed on the first electrode branch AE2 and extended in the second direction DR2. The first contact electrode CTE1 may contact first ends of the light-emitting elements ED. The light-emitting elements ED may be electrically connected to the first electrode AE through the first contact electrode CTE1.

The first contact electrode CTE1 may directly contact the upper surface of one end of the second element insulating layer QPAS2.

The second contact electrode CTE2 may be disposed on the second electrode branch CE2 and extended in the second direction DR2. The second contact electrode CTE2 may be spaced apart from the first contact electrodes CTE1 in the first direction DR1. The second contact electrode CTE2 may contact second ends of the light-emitting elements ED. The light-emitting elements ED may be electrically connected to the second electrode CE through the second contact electrode CTE2.

The second contact electrode CTE2 may be directly contact the upper surface of the opposite end of the second element insulating layer QPAS2.

The first contact electrode CTE1 and the second contact electrode CTE2 may be formed on the same layer. Each of the first contact electrode CTE1 and the second contact electrode CTE2 may expose the upper surface of the center of the second element insulating layer QPAS2.

Each of the first contact electrode CTE1 and the second contact electrode CTE2 may include a conductive material. The first contact electrode CTE1 may include a first material, and the second contact electrode CTE2 may include a second material. It should be noted that the first material and the second material may have different physical properties. A more detailed description thereon will be given below.

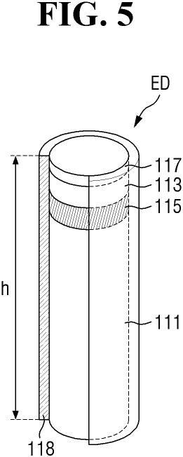

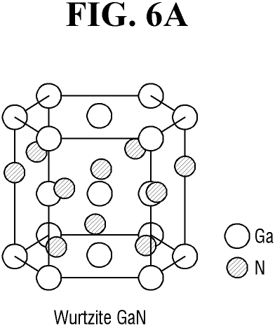

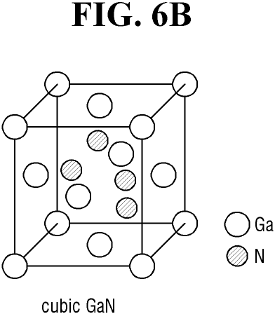

FIG. 5 is a perspective view showing a light-emitting element according to an embodiment of the disclosure. FIGS. 6A and 6B are perspective views showing hexagonal gallium nitride (h-GaN/Wurtzite GaN) and cubic gallium nitride (c-GaN), respectively.

Referring to FIGS. 5, 6A, and 6B, the light-emitting element ED may be a light-emitting diode. For example, the light-emitting elements ED may have a size of a micro-meter or a nano-meter, and may be an inorganic light emitting diode containing an inorganic material. Inorganic light-emitting diodes may be aligned between two electrodes facing each other by an electric field formed in a particular direction between the two electrodes.

The light-emitting element ED may have a shape extended in one direction. The light-emitting element ED may have a shape of a rod, wire, tube, etc. The light-emitting element ED may include a first semiconductor layer 111, a second semiconductor layer 113, an active layer 115, an electrode layer 117, and an insulating layer 118. The length h of the light-emitting element ED may be approximately 4 µm.

The first semiconductor layer 111 may be an n-type semiconductor. The first semiconductor layer 111 may include a semiconductor material having the following chemical formula: AlₓGa_{y}In_{1-x-y}N (0≤x≤1, 0≤y≤1, 0≤x+y≤1). For example, the first semiconductor layer 111 may be at least one of n-type doped AlGaInN, GaN, AlGaN, InGaN, AlN and InN. The first semiconductor layer 111 may be doped with an n-type dopant, and the n-type dopant may be Si, Ge, Sn, etc. For example, the first semiconductor layer 111 may be n-GaN doped with n-type Si. The thickness of the first semiconductor layer 111 may range, but is not limited to, from about 500 nm to about 1 µm. For example, the first semiconductor layer 111 may include hexagonal gallium nitride (h-GaN) doped with n-type Si (see FIG. 6A) and cubic gallium nitride (c-GaN) (see FIG. 6B).

The second semiconductor layer 113 may be p-type semiconductor, and may include a semiconductor material having the following chemical formula: AlₓGa_{y}In_{1-x-y}N (0≤x≤1, 0≤y≤1 and 0≤x+y≤1). For example, the second semiconductor layer 113 may be at least one of p-type doped AlGaInN, GaN, AlGaN, InGaN, AlN and InN. The second semiconductor layer 113 may be doped with a p-type dopant, and the p-type dopant may be Mg, Zn, Ca, Ba, etc. For example, the second semiconductor layer 113 may be p-GaN doped with p-type Mg. The second semiconductor layer 113 may have a thickness in a range of about 30 nm to about 200 nm. For example, the second semiconductor layer 113 may include hexagonal gallium nitride (h-GaN) doped with p-type Si and cubic gallium nitride (c-GaN).

The active layer 115 may be disposed between the first semiconductor layer 111 and the second semiconductor layer 113. The active layer 115 may emit light as electrons and holes are recombined therein in response to an emission signal applied through the first semiconductor layer 111 and the second semiconductor layer 113. The active layer 115 may include a material having a single or multiple quantum well structure. In case that the active layer 115 includes a material having multiple quantum well structure, well layers and barrier layers may be alternately stacked each other in the structure. For example, the active layer 115 may have a structure in which a semiconductor material having a large band gap energy and a semiconductor material having a small band gap energy are alternately stacked each other, and may include Group III to Group V semiconductor materials depending on the wavelength range of the emitted light.

Although not shown in the drawings, a superlattice layer may be further disposed between the active layer 115 and the first semiconductor layer 111. The superlattice layer may relieve stress due to a difference in lattice constants between the first semiconductor layer 111 and the active layer 115. For example, the superlattice layer may be made of InGaN or GaN. The thickness of the superlattice layer may range from approximately 50 to approximately 200 nm.

According to an embodiment, some of the light-emitting elements ED of the display device 1 may include different active layers 115 to emit lights of different colors. For example, the active layer 115 of the light-emitting element ED of the first light-emitting area LA1 may emit red light of the first color, the active layer 115 of the light-emitting element ED of the second light-emitting area LA2 may emit green light of the second color, and the active layer 115 of the light-emitting element ED of the third light-emitting area LA3 may emit blue light of the third color. The light-emitting element ED of the first light-emitting area LA1, the light-emitting element ED of the second light-emitting area LA2, and the light-emitting element ED of the third light-emitting emitting area LA3 may have different concentrations of dopants doped into the first semiconductor layer 111, the active layer 115, and the second semiconductor layer 113, or may have different values of x and y in the formula: AlₓGa_{y}In_{1-x-y}N (0≤x≤1,0≤y≤1 and 0≤ x+y≤1).

For example, in case that the active layer 115 contains InGaN, the active layers 115 may emit lights of different colors depending on the content of indium (In). For example, as the content of indium (In) increases, the wavelength range of light output from the active layers 115 may move to the red wavelength range, and as the content of indium (In) decreases, the wavelength range of the output light may move to the blue wavelength range. Therefore, the content of indium (In) in the active layer 115 of the light-emitting element ED of the first light-emitting area LA1 may be higher than the content of indium (In) in the active layer 115 of the light-emitting element ED of each of the second light-emitting area LA2 and the third light-emitting area LA3. The content of indium (In) in the active layer 115 of the light-emitting element ED of the second light-emitting area LA2 may be higher than the content of indium (In) in the active layer 115 of the light-emitting element ED of the third light-emitting LA3.

For example, the content of indium (In) in the active layer 115 of the light-emitting element ED of the third light-emitting area LA3 may be approximately 5% to approximately 10%, the content of indium (In) in the active layer 115 of the light-emitting element ED of the second light-emitting area LA2 may be approximately 10% to approximately 15%, and the content of indium (In) in the active layer 115 of the light-emitting element ED of the first light-emitting area LA1 may be approximately 20% to approximately 25%. For example, by adjusting the content of indium (In) in the active layers 115, the light-emitting elements ED may emit light of different colors.

According to an embodiment of the disclosure, such contents of indium (In) in the active layer 115 of the light-emitting element ED in each of the light-emitting areas LA1, LA2, and LA3 may be achieved as the crystal structure of the active layer 115 includes cubic gallium nitride (c-GaN). The crystal structure of the active layer 115 of the light-emitting element ED in each of the light-emitting areas LA1, LA2, and LA3 according to the embodiment may be formed only of cubic gallium nitride (c-GaN). For example, the active layer 115 of the light-emitting element ED in each of the light-emitting areas LA1, LA2, and LA3 may be formed only of cubic gallium nitride (c-GaN) and doped with a dopant (for example, indium (In)) in a later step.

Typically, in case that the crystal structure of the active layer 115 of the light-emitting element ED in each of the light-emitting areas LA1, LA2, and LA3 is formed of hexagonal gallium nitride (h-GaN), the content of indium (In) in the active layer 115 of the light-emitting element ED of the third light-emitting area LA3 may be approximately 15%, the content of indium (In) in the active layer 115 of the light-emitting element ED of the second light-emitting area LA2 may be approximately 25%, and the content of indium (In) in the active layer 115 of the light-emitting element ED of the first light-emitting area LA1 may be approximately 35% or more.

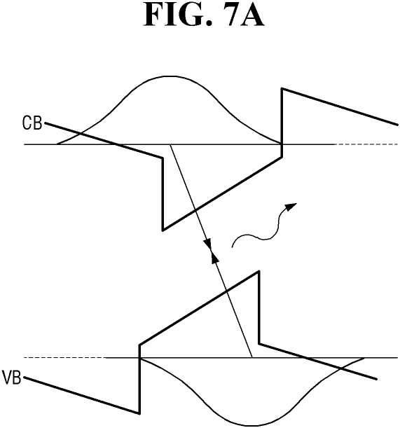

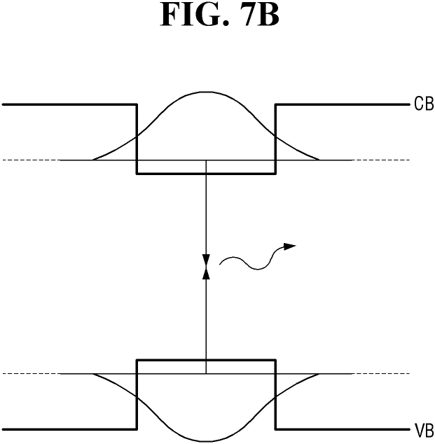

FIGS. 7A and 7B are views showing energy bands of hexagonal gallium nitride (h-GaN/Wurtzite GaN) and cubic gallium nitride (c-GaN), respectively.

Referring to FIGS. 5 to 7B, the energy band gap of hexagonal gallium nitride (h-GaN) may be approximately 3.4 eV, and the energy band gap of cubic gallium nitride (c-GaN) may be approximately 3.2 eV. As shown in FIG. 7A, the conduction band CB and the valence band VB of the hexagonal gallium nitride (h-GaN) may have horizontal asymmetry. As shown in FIG. 7B, the conduction band CB and the valence band VB of the cubic gallium nitride (c-GaN) may have horizontal symmetry. Since the conduction band CB and the valence band VB of the hexagonal gallium nitride (h-GaN) have horizontal asymmetry, the active layer having the crystal structure of the hexagonal gallium nitride (h-GaN) may have a polarization state (including a polarization material). On the contrary, since the conduction band CB and the valence band VB of the cubic gallium nitride (c-GaN) have horizontal symmetry, the active layer 115 having the crystal structure of the cubic gallium nitride (c-GaN) may have a non-polarization state (including a non-polarization material). More specifically, the non-polarization material may include cubic gallium nitride (c-GaN).

Furthermore, since the conduction band CB and the valence band VB of the hexagonal gallium nitride (h-GaN) have horizontal asymmetry, the energy band gap may be greater than the energy bandgap of the active layer 115 in which the conduction band CB and the valence band VB of the cubic gallium nitride (c-GaN) which has horizontal symmetry.

Furthermore, since the energy band gap of the cubic gallium nitride (c-GaN) is smaller than that of the hexagonal gallium nitride (h-GaN), it is possible to emit light of the same color even with less contents of indium (In) (the content of indium (In) in the active layer 115 of the light-emitting element ED of the third light-emitting area LA3 is approximately 5% to approximately 10%, the content of indium (In) in the active layer 115 of the light-emitting element ED of the second light-emitting area LA2 is approximately 10% to approximately 15%, and the content of indium (In) in the active layer 115 of the light-emitting element ED of the first light-emitting area LA1 is approximately 20% to approximately 25%) than the crystal structure of the active layer 115 of the light-emitting element ED of each of the light-emitting areas LA1, LA2, and LA3 formed of the hexagonal gallium nitride (h-GaN) (the content of indium (In) in the active layer 115 of the light-emitting element ED in the third light-emitting area LA3 is approximately 15%, the content of indium (In) in the active layer 115 of the light-emitting element ED in the second light-emitting area LA2 is approximately 25%, and the content of indium (In) in the active layer 115 of the light-emitting element ED I the first light-emitting area LA1 is approximately 35% or more).

For example, the active layer 115 formed only of cubic gallium nitride (c-GaN) requires less content of indium (In), and thus the emission efficiency may be better than the active layer formed of hexagonal gallium nitride (h-GaN).

Hereinafter, a method of fabricating a display device according to an embodiment of the disclosure will be described. In the following description, the same or similar elements will be denoted by the same or similar reference numerals, and redundant descriptions will be omitted or briefly described.

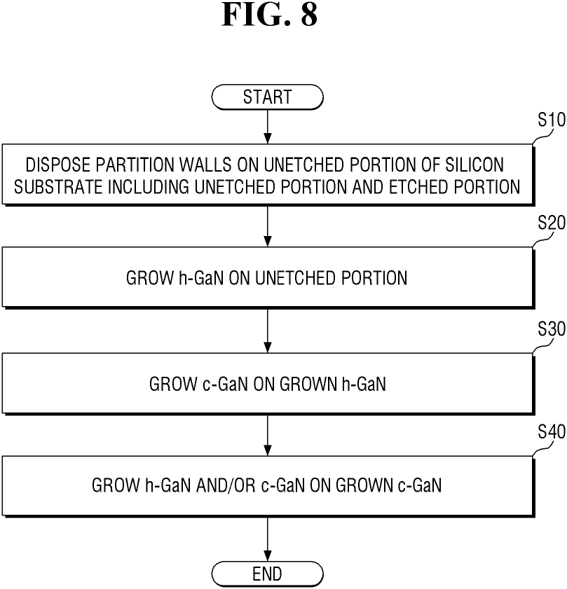

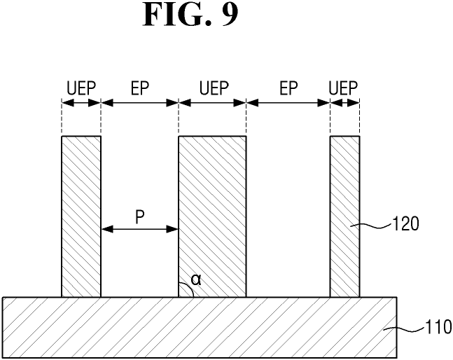

FIG. 8 is a flowchart illustrating a method for fabricating a display device according to an embodiment of the disclosure. FIGS. 9 to 11 are schematic cross-sectional views showing processing steps of a method of fabricating a display device according to an embodiment of the disclosure. A method of fabricating a display device will be described with reference to FIGS. 8 to 11 in conjunction with FIG. 4.

A method of fabricating a display device according to an embodiment may include preparing a substrate where first banks BNK1 spaced apart from one another are disposed.

Subsequently, the method may include forming a first electrode AE and a second electrode CE that are disposed on the first banks BNK1 to cover the first banks BNK1 and are spaced apart from each other.

Subsequently, the method may include forming a first element insulating layer QPAS1 on the first electrode AE and the second electrode CE.

Subsequently, the method may include disposing a light-emitting element ED between the first electrode AE and the second electrode CE on the first element insulating layer QPAS1.

The disposing the light-emitting element may include forming the light-emitting element ED and disposing the light-emitting element ED between the first electrode AE and the second electrode CE.

As shown in FIGS. 8 and 9, the forming the light-emitting element ED may include disposing the partition walls or banks 120 on an unetched portion UEP of the silicon substrate 110 including and the unetched portion UEP and an etched portion EP (step S10).

The banks 120 may include an inorganic insulating material. The inorganic insulating material may include, but is not limited to, silicon oxide (SiO₂).

The banks 120 may be disposed to have a first inclination angle α with respect to the upper surface of the silicon substrate 110. The first inclination angle α may be, for example, about 45 degrees to about 90 degrees.

The pitch P of the banks 120 may be approximately 5,800 nm to approximately 6,000 nm.

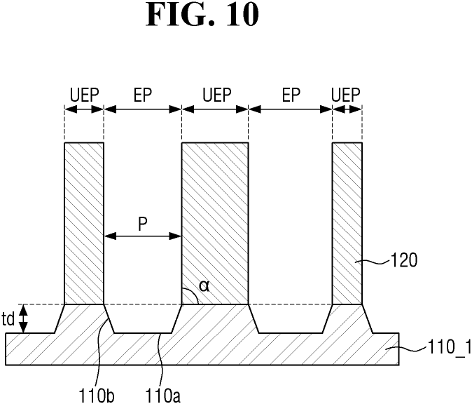

Referring to FIGS. 8 and 10, the forming the light-emitting element ED may include forming a first etched surface 110a and a second etched surface 110b in the etched portion EP after the disposing S10 the banks 120 on the unetched portion UEP of the silicon substrate 110.

The etched portion EP of a silicon substrate 110_1 may include a first etched surface 110a and a second etched surface 110b between the first etched surface 110a and the upper surface of the unetched portion UEP. The second etched surface 110b may be inclined with respect to the first etched surface 110a. For example, the etch depth td of the first etched surface 110a may be approximately 50 nm to approximately 150 nm.

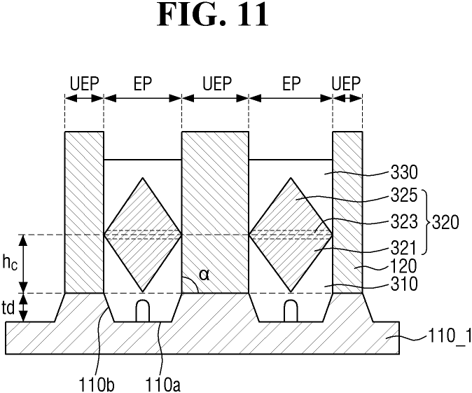

Referring to FIGS. 8 and 11, the forming the light-emitting element ED may include growing hexagonal gallium nitride (h-GaN) 310 on the etched portion EP (step S20) after the forming the first etched surface 110a and the second etched surface 110b in the etched portion EP. The growing S20 the hexagonal gallium nitride (h-GaN) may include growing the hexagonal gallium nitride (h-GaN) 310 from the first etched surface 110a and the second etched surface 110b of the silicon substrate 110_1 (the surface grown from the first etched surface 110a may be (110) surface and the surface grown from the second etched surface 110b may be (111) surface).

Subsequently, referring to FIGS. 8 and 11, the forming the light-emitting element ED may include growing cubic gallium nitride (c-GaN) 320 on the grown hexagonal gallium nitride (h-GaN) 310 (step S30) after the growing S20 the hexagonal gallium nitride (h-GaN) 310 on the etched portion EP.

Subsequently, referring to FIGS. 8 and 11, the forming the light-emitting element ED may include growing hexagonal gallium nitride (h-GaN) and/or cubic gallium nitride (c-GaN) 330 on the grown cubic gallium nitride (c-GaN) 320 after the growing S30 the cubic gallium nitride (c-GaN) on the grown hexagonal gallium nitride (h-GaN). In the growing the cubic gallium nitride (c-GaN) 320 on the grown hexagonal gallium nitride (h-GaN) 310, the cubic gallium nitride (c-GaN) 320 may completely cover the hexagonal gallium nitride (h-GaN) 310.

As shown in FIG. 11, the grown hexagonal gallium nitride (h-GaN) 310 and a first portion 321 of the grown cubic gallium nitride (c-GaN) 320 may form the first semiconductor layer 111 of FIG. 5. A second portion 323 of the grown cubic gallium nitride (c-GaN) 320 may form the active layer 115 of FIG. 5. A third portion 325 of the grown cubic gallium nitride (c-GaN) 320 and the grown hexagonal gallium nitride (h-GaN) and/or the cubic gallium nitride (c-GaN) 330 may form the second semiconductor layer 113.

The height hc of the active layer 115 from the upper surface of the unetched portion of the silicon substrate 110_1 may be approximately 50 nm to approximately 100 nm.

As described above with reference to FIG. 5, in order to fabricate the light-emitting element ED with a length h of approximately 4 µm, the second portion 323 may be located at a predetermined (or selectable) height hc from the upper surface of the unetched portion of the silicon substrate 110_1.

The predetermined (or selectable) height hc from the upper surface of the unetched portion of the silicon substrate 110_1 may be calculated based on the following Equation 1.

$${h}_{c} = \frac{1.06 p - 0.75 {t}_{d}}{1 - tan α / 0.71}$$

As described above, since the energy band gap of the cubic gallium nitride (c-GaN) is smaller than that of the hexagonal gallium nitride (h-GaN), it is possible to emit light of the same color even with less contents of indium (In) (the content of indium (In) in the active layer 115 of the light-emitting element ED of the third light-emitting area LA3 is approximately 5% to approximately 10%, the content of indium (In) in the active layer 115 of the light-emitting element ED of the second light-emitting area LA2 is approximately 10% to approximately 15%, and the content of indium (In) in the active layer 115 of the light-emitting element ED of the first light-emitting area LA1 is approximately 20% to approximately 25%) than the crystal structure of the active layer 115 of the light-emitting element ED of each of the light-emitting areas LA1, LA2, and LA3 formed of the hexagonal gallium nitride (h-GaN) (the content of indium (In) in the active layer 115 of the light-emitting element ED in the third light-emitting area LA3 is approximately 15%, the content of indium (In) in the active layer 115 of the light-emitting element ED in the second light-emitting area LA2 is approximately 25%, and the content of indium (In) in the active layer 115 of the light-emitting element ED I the first light-emitting area LA1 is approximately 35% or more).

For example, the active layer 115 formed only of the cubic gallium nitride (c-GaN) requires less content of indium (In), and thus the emission efficiency may be better than the active layer containing hexagonal gallium nitride (h-GaN).

Hereinafter, display devices according to another embodiment of the disclosure will be described.

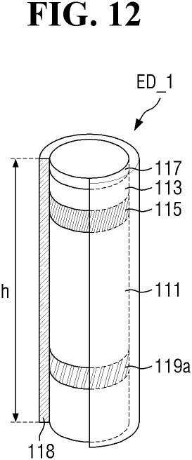

FIG. 12 is a perspective view showing a light-emitting element according to another embodiment of the disclosure.

Referring to FIG. 12, a light-emitting element ED_1 according to the embodiment may further include an undoped semiconductor layer 119a. The undoped semiconductor layer 119a may be spaced apart from an active layer 115 with a first semiconductor layer 111 interposed therebetween. The undoped semiconductor layer 119a may include one of AlGaInN, GaN, AlGaN, InGaN, AlN and InN.

The other elements may be identical to those described above with reference to FIG. 5; and, therefore, the redundant description will be omitted.

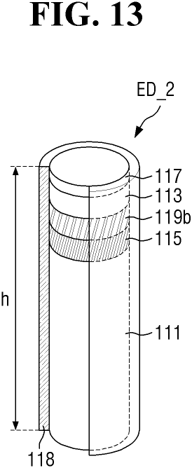

FIG. 13 is a perspective view showing a light-emitting element according to yet another embodiment of the disclosure.

A light-emitting element ED_2 according to the embodiment of FIG. 13 is different from the light-emitting element ED according to the embodiment of FIG. 5 in that the former may further include an electron blocking layer 119b. The electron blocking layer 119b may be disposed between the active layer 115 and the second semiconductor layer 113. The electron blocking layer 119b may prevent that electrons flowing into the active layer 115 fail to recombine with holes in the active layer 115 and are injected into other layers. For example, the electron blocking layer 119b may be p-AlGaN doped with p-type Mg. A thickness of the electron blocking layer 119b may be in a range of about 10 nm to about 50 nm, but the disclosure is not limited thereto.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A display device comprising:
first banks spaced apart from one another and disposed on a substrate;
a first electrode and a second electrode, each disposed on one of the first banks to cover each respective first bank and spaced apart from each other; and
a light-emitting element disposed between the first electrode and the second electrode, wherein
the light-emitting element comprises an active layer,
the active layer is in a non-polarized state, and
the active layer includes cubic gallium nitride (c-GaN).

2. The display device of claim 1, wherein the active layer comprises only cubic gallium nitride (c-GaN).

3. The display device of claim 1, wherein the light-emitting element further comprises:
a first semiconductor layer between the active layer and the second electrode; and
a second semiconductor layer between the active layer and the first electrode.

4. The display device of claim 3, wherein the first semiconductor layer includes GaN doped with n-type Si.

5. The display device of claim 4, wherein the first semiconductor layer includes n-type Si doped hexagonal gallium nitride (h-GaN) and cubic gallium nitride (c-GaN).

6. The display device of claim 5, wherein the second semiconductor layer includes GaN doped with p-type Si.

7. The display device of claim 6, wherein the second semiconductor layer includes p-type Si doped hexagonal gallium nitride (h-GaN) and cubic gallium nitride (c-GaN).

8. The display device of claim 7, wherein the active layer completely covers the hexagonal gallium nitride (h-GaN) of the first semiconductor layer.

9. The display device of claim 3, further comprising:
a first contact electrode electrically connected to the first electrode and contacting the second semiconductor layer of the light-emitting element.

10. The display device of claim 9, further comprising:
a second contact electrode electrically connected to the second electrode and contacting the first semiconductor layer of the light-emitting element.

11. The display device of claim 10, further comprising:
a first element insulating layer disposed between the first electrode, the second electrode, and the light-emitting element; and
a second element insulating layer disposed on an upper surface of the light-emitting element, wherein
the first contact electrode directly contacts a portion of an upper surface of the second element insulating layer,
the second contact electrode directly contacts another portion of the upper surface of the second element insulating layer, and
each first contact electrode and the second contact electrode exposes a central portion of the upper surface of the second element insulating layer.

12. The display device of claim 11, further comprising:
a third element insulating layer integrally formed to cover the first contact electrode and the second contact electrode and contacting the first contact electrode and the second contact electrode.

13. A method of fabricating a display device, the method comprising:
preparing a substrate on which first banks spaced apart from one another are disposed;
forming a first electrode and a second electrode on one of the first banks to cover respective first bank, the first electrode and the second electrode being spaced apart from each other;
forming a first element insulating layer on the first electrode and the second electrode; and
disposing a light-emitting element on the first element insulating layer, wherein
the disposing the light-emitting element comprises:
forming the light-emitting element; and
disposing the light-emitting element between the first electrode and the second electrode,
the forming the light-emitting element comprises:
disposing second banks on an unetched portion of a silicon substrate comprising the unetched portion and an etched portion;
growing first hexagonal gallium nitride (h-GaN) on the etched portion;
growing first cubic gallium nitride (c-GaN) on the first hexagonal gallium nitride (h-GaN); and
growing second hexagonal gallium nitride (h-GaN) and/or second cubic gallium nitride (c-GaN) on the first cubic gallium nitride (c-GaN).

14. The method of claim 13, wherein the light-emitting element comprises:
an active layer;
a first semiconductor layer between the active layer and the second electrode; and
a second semiconductor layer between the active layer and the first electrode.

15. The method of claim 14, wherein the active layer is formed only of cubic gallium nitride (c-GaN).

16. The method of claim 15, wherein
the second banks comprise silicon oxide, and
a distance between the second banks is in a range of about 5,800 nm to about 6,000 nm.

17. The method of claim 16, wherein
the etched portion comprises:
a first etched surface; and
a second etched surface between the first etched surface and an upper surface of the unetched portion, and
the second etched surface is inclined with respect to the first etched surface.

18. The method of claim 17, wherein a depth of the first etched surface is in a range of about 50 nm to about 150 nm.

19. The method of claim 18, wherein a height of the active layer from the upper surface of the unetched portion of the silicon substrate is in a range of about 50 nm to about100 nm.

20. The method of claim 13, wherein the growing the first cubic gallium nitride (c-GaN) on the first hexagonal gallium nitride (h-GaN) comprises:
growing the first cubic gallium nitride (c-GaN) to completely cover the first hexagonal gallium nitride (h-GaN).
